(19) United States
(12) Patent Application Publication
(10) Pub. No.: US 2008/0055869 A1
(43) Pub. Date: Mar. 6, 2008

(54) CIRCUIT BOARD CARRIER

(75) Inventor: Chen Cheng Hsiung, Taipei City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, omitted

(73) Assignee: COMPAL ELECTRONICS, INC., Taipei City (TW)

(21) Appl. No.: 11/781,968

(22) Filed: Jul. 24, 2007

(30) Foreign Application Priority Data
Sep. 5, 2006 (TW) 95132704

(51) Int. Cl. H05K 5/02; H05K 1/00

(52) U.S. Cl. 361/752; 361/748

(57) ABSTRACT

A circuit board carrier suitable for carrying a circuit board includes a first frame and a second frame. The second frame is formed by connecting a plurality of modulized components and is assembled with the first frame. The second frame has a plurality of supporting portions to support the circuit board at a surface thereof. Since the second frame of the circuit board carrier is formed by assembling a plurality of modulized components with smaller sizes, therefore, only less waste material is produced during manufacturing the second frame, which is advantageous in reducing production cost. In addition, the supporting portions of the circuit board carrier are capable of supporting the circuit board at the edges and the inner portion of the bottom of the circuit board, which is advantageous in reducing the twist deformation of the circuit board after passing through a solder pot.

### CROSS-REFERENCE TO RELATED APPLICATION

This application claims the priority benefit of Taiwan application serial no. 95132704, filed Sep. 5, 2006. All disclosure of the Taiwan application is incorporated herein by reference.

### BACKGROUND OF THE INVENTION

1. Field of the Invention

The present invention generally relates to a circuit board carrier, and more particularly, to a circuit board carrier for carrying a circuit board to pass through a solder pot.

2. Description of Related Art

Currently, mounting electronic components onto a circuit board mainly has two joining modes: pin through hole (PTH) and surface mount technology (SMT). In terms of PTH, the pins of electronic components would be inserted into and passing through the drilled holes of a circuit board, following by soldering the pins with the circuit board using solder paste, wherein a so-called dual inline package (DIP) electronic component is most popular and representative by mounting in PTH mode. In terms of SMT, the ends of the leads of electronic components would be directly joined onto pads on a circuit board by using solder paste without passing through the circuit board.

In the above-mentioned mounting process, a circuit board is required to pass through a solder pot by means of a circuit board carrier, so that the solder paste is melted by heating in the solder pot, and the liquid solder alloy embraces the pins (or leads) of the electronic components and the pads of the circuit board. After the liquid solder alloy is cooled and frozen, the solder alloy in solid state fixes the pins (or leads) of the electronic components onto the circuit board. Meanwhile, the pins (or leads) of the electronic components are electrically connected to the pads of the circuit board.

However, a conventional circuit board carrier usually supports along the surrounding edges of the circuit board only. As a consequence, when the circuit board passes through a solder pot, the central area of the circuit board may get twist deformation due to insufficient support. Moreover, when a conventional circuit board carrier is used to carry circuit boards with different outer profiles, a new die is required for the same circuit board carrier, which leads to a higher production cost.

### SUMMARY OF THE INVENTION

Accordingly, the present invention is directed to provide a circuit board carrier to lower production cost.

The present invention is also directed to provide a circuit board carrier capable of supporting the circuit board at the edges and the inner portion of the bottom of the circuit board, which is advantageous in reducing the twist deformation of the circuit board after passing through a solder pot.

As embodied and broadly described herein, the present invention provides a circuit board carrier for carrying a circuit board. The circuit board carrier includes a first frame and a second frame. The second frame is formed by connecting a plurality of modulized components and is assembled with the first frame. The second frame has a plurality of supporting portions to support the circuit board at a surface thereof.

In an embodiment of the present invention, the above-mentioned first frame includes an outer frame and a plurality of supporting beams, wherein the supporting beams are connected to the outer frame and are assembled to the outer frame by using screws.

In an embodiment of the present invention, the above-mentioned first frame has a plurality of assembling holes and the second frame is assembled to the first frame by using a part of the assembling holes.

In an embodiment of the present invention, the above-mentioned modulized components are assembled into the second frame following the profile of a side frame of the circuit board.

In an embodiment of the present invention, the above-mentioned modulized components are assembled into the second frame by using screws.

In an embodiment of the present invention, the above-mentioned second frame is assembled to the first frame by using screws and thermosetting plastic.

In an embodiment of the present invention, any one of the above-mentioned supporting portions includes a supporting block protruded from the second frame to contact the surface of the circuit board.

In an embodiment of the present invention, any one of the above-mentioned supporting portions includes a supporting post protruded from the second frame to contact the surface of the circuit board.

In an embodiment of the present invention, the above-mentioned second frame has a plurality of positioning portions protruded from the second frame to position the circuit board onto the second frame.

In an embodiment of the present invention, the above-mentioned positioning portions include a plurality of positioning pins protruded from the second frame to respectively pass through a plurality of through holes of the circuit board to position the circuit board onto the second frame.

As embodied and broadly described herein, the present invention provides a circuit board carrier for carrying a circuit board. The circuit board carrier includes a first frame and a second frame. The first frame includes an outer frame and a supporting beam, and the outer frame and the supporting beam are connected to each other. The second frame is formed by connecting a plurality of modulized components and is assembled with the first frame. The second frame has a plurality of supporting portions to support the circuit board at a surface thereof.

In an embodiment of the present invention, the above-mentioned outer frame and the supporting beam are connected to each other by using a plurality of fasteners.

In an embodiment of the present invention, the above-mentioned first frame has a plurality of assembling holes and the second frame is assembled to the first frame by using a part of the assembling holes.

In an embodiment of the present invention, the above-mentioned modulized components are assembled into the second frame following the profile of a side frame of the circuit board.

In an embodiment of the present invention, the above-mentioned modulized components are assembled into the second frame by using screws.

In an embodiment of the present invention, the above-mentioned second frame is assembled to the first frame by using screws and thermosetting plastic.

In an embodiment of the present invention, any one of the above-mentioned supporting portions includes a supporting block protruded from the second frame to contact the surface of the circuit board.

In an embodiment of the present invention, any one of the above-mentioned supporting portions includes a supporting post protruded from the second frame to contact the surface of the circuit board.

In an embodiment of the present invention, the above-mentioned second frame has a plurality of positioning portions protruded from the second frame to position the circuit board onto the second frame.

In an embodiment of the present invention, the above-mentioned positioning portions include a plurality of positioning pins protruded from the second frame to respectively pass through a plurality of through holes of the circuit board to position the circuit board onto the second frame.

Since the second frame of the present invention is formed by assembling a plurality of modulized components with smaller sizes, thus, only less waste material is produced during manufacturing the second frame, which is advantageous in reducing production cost. In addition, the supporting portions of the present invention are capable of supporting the circuit board at the edges and the inner portion of the bottom of the circuit board, which is advantageous in reducing the twist deformation of the circuit board after passing through a solder pot.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a 3-D diagram of a circuit board carrier with a circuit board prior to assembling the same according to an embodiment of the present invention.

FIG. 2 is a 3-D exploded diagram of the first frame as shown in FIG. 1.

FIG. 3 is a 3-D exploded diagram of the second frame as shown in FIG. 1.

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

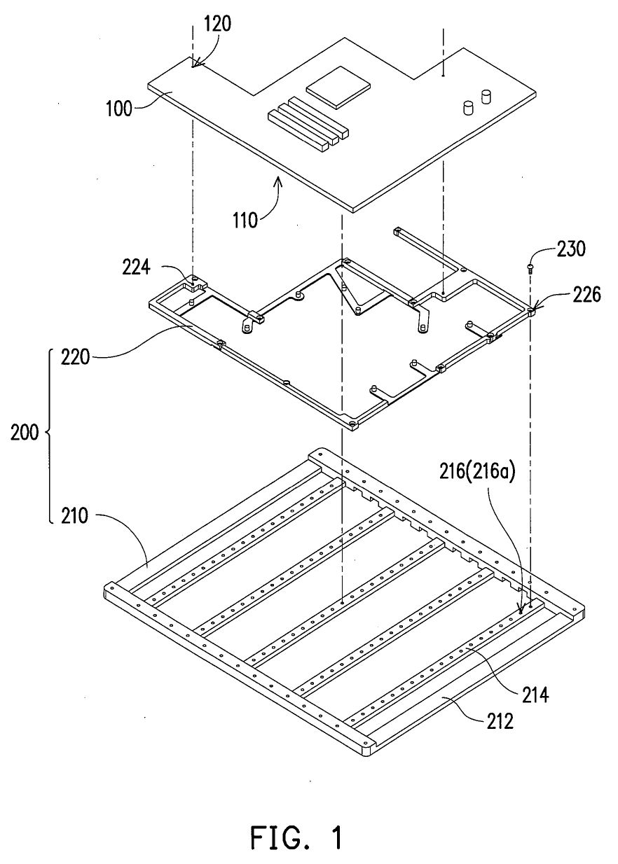

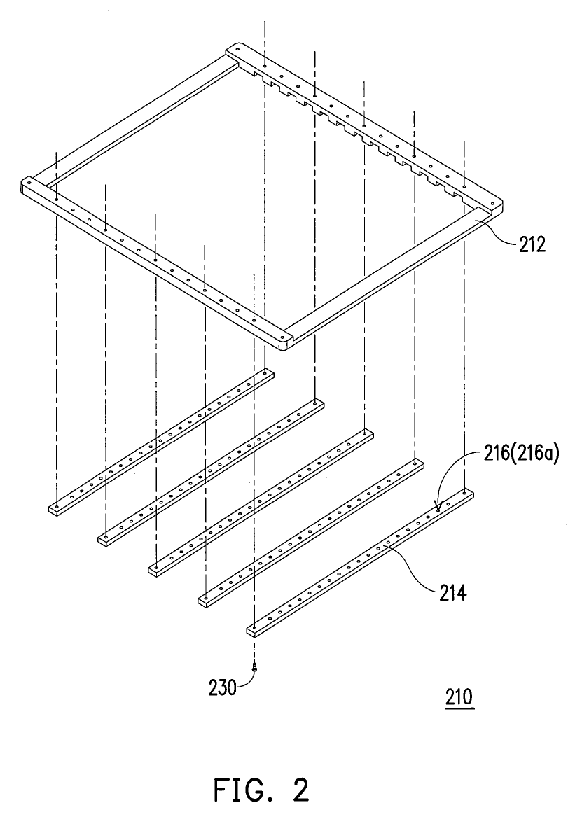

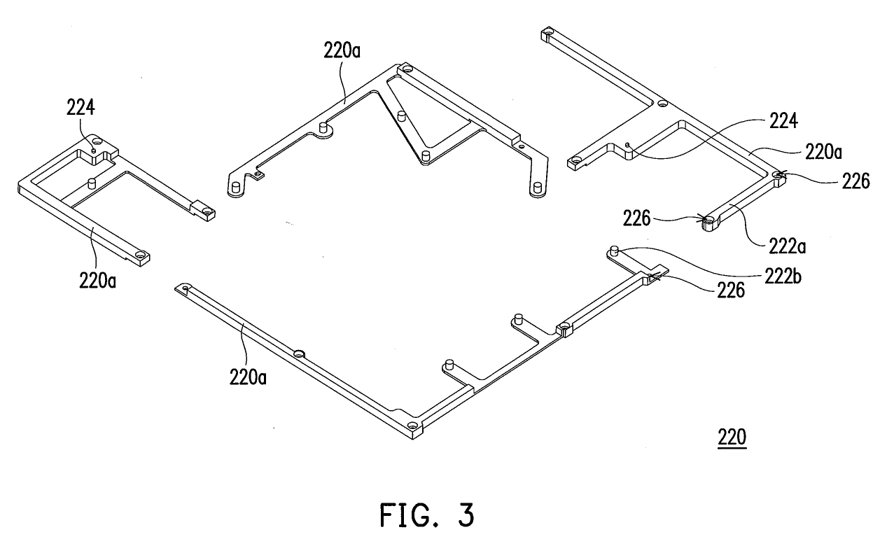

FIG. 1 is a 3-D diagram of a circuit board carrier with a circuit board prior to assembling the same according to an embodiment of the present invention, FIG. 2 is a 3-D exploded diagram of the first frame as shown in FIG. 1 and FIG. 3 is a 3-D exploded diagram of the second frame as shown in FIG. 1. Referring to FIGS. 1 to 3, a circuit board carrier 200 is suitable for carrying a circuit board 100. The circuit board carrier 200 includes a first frame 210 and a second frame 220. The first frame 210 includes an outer frame 212 and one or a plurality of supporting beams 214, and the outer frame 212 and the supporting beams 214 are connected to each other. The second frame 220 is formed by connecting a plurality of modulized components 220a, and the modulized components 220a are suitable to be assembled to the first frame 210.

The second frame 220 has a plurality of supporting portions for supporting the circuit board 100 at a surface 110 thereof. In the present embodiment, the supporting portions can include a plurality of supporting blocks 222a and a plurality of supporting posts 222b. The supporting blocks 222a are capable of supporting the circuit board 100 at edges of the surface 110 of the circuit board 100, while the supporting posts 222b are for supporting the circuit board 100 at the inner portion of the surface 110 of the circuit board 100.

Continuing to FIG. 2, in the first frame 210, the outer frame 212 and the supporting beams 214 are connected to each other by using a plurality of fasteners 230. In the present embodiment, the fasteners 230 are, for example, bolt, rivet or latch pin. However, the outer frame 212 and the supporting beams 214 can be connected to each other without the fasteners 230. For example, the outer frame 212 and the supporting beams 214 can be connected to each other by inlaying. In addition, the outer frame 212 and the supporting beams 214 can be connected to each other by using thermosetting plastic (not shown) more firmly and without risk of getting loosened even off.

Referring to FIGS. 1 to 3, the first frame 210 can also have a plurality of assembling holes 216, and the second frame 220 can be assembled to the first frame 210 by means of the assembling holes 216. In the present embodiment, the first frame 210 has a plurality of first assembling holes 216a, while the modulized components 220a of the second frame 220 can have a plurality of second assembling holes 226. The second frame 220 can be assembled to the first frame 210 by using the fasteners 230 to pass through the first assembling holes 216a and the second assembling holes 226. Similarly, the fasteners 230 are, for example, bolt, rivet or latch pin. The second frame 220 can be assembled to the first frame 210 by inlaying. In addition, during assembling the second frame 220 to the first frame 210, thermosetting plastic can be used to make the connection therebetween more firmly and without risk of getting loosened even off.

Besides, the shapes of the modulized components 220a can be designed following the profile of the side frames of the circuit board 100 for assembling the modulized components 220a into the second frame 220, and the modulized components 220a are connected to each other by using the fasteners 230 to form the second frame 220. Similarly, the fasteners 230 are, for example, bolt, rivet or latch pin. The modulized components 220a can be assembled to the second frame 220 by inlaying. In addition, during assembling the modulized components 220a to the second frame 220, thermosetting plastic can be used to make the connection therebetween more firmly and without risk of getting loosened even off. In the present embodiment, the fasteners 230 can respectively pass through the second assembling holes 226 of the plurality of the modulized components 220a and the first assembling holes 216a of the first frame 210 for assembling the modulized components 220a onto the first frame 210.

Furthermore, the second frame 220 can also have a plurality of positioning portions. The positioning portions are protruded from the second frame 220 to position the circuit board 100 onto the second frame 220. In the present embodiment, the positioning portions can be positioning pins 224 protruded from the second frame 220, while the circuit board 100 can have a plurality of through holes 120. When the circuit board 100 is mounted onto the second frame 220, the positioning pins 224 are suitable to be inserted into a part of the through holes 120 for positioning the circuit board 100 onto the second frame 220. However, the positioning portions are not limited to the positioning pins 224. For example, the positioning portions can be ribs (not shown) protruded from the second frame 220. When the circuit board 100 is mounted onto the second frame 220, the ribs are suitable to surround the circuit board 100 so as to position the circuit board 100 onto the second frame 220.

In summary, since the second frame of the present invention is formed by assembling a plurality of modulized components with smaller sizes, thus, only less waste material is produced during manufacturing the second frame, which is advantageous in reducing production cost. In addition, the supporting portions of the present invention are capable of supporting the circuit board at the edges and the inner portion of the bottom of the circuit board, which is advantageous in reducing the twist deformation of the circuit board after passing through a solder pot.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A circuit board carrier, suitable for carrying a circuit board; the circuit board carrier comprising:
a first frame, comprising an outer frame and a supporting beam, wherein the outer frame and the supporting beam are connected to each other; and
a second frame, formed by connecting a plurality of modulized components and assembled with the first frame, wherein the second frame has a plurality of supporting portions to support a surface of the circuit board.

2. The circuit board carrier according to claim 1, wherein the outer frame and the supporting beam are connected to each other by using a plurality of fasteners.

3. The circuit board carrier according to claim 1, wherein the first frame has a plurality of assembling holes and the second frame is assembled to the first frame by using a part of the assembling holes.

4. The circuit board carrier according to claim 1, wherein the modulized components are assembled into the second frame following the profile of a side frame of the circuit board.

5. The circuit board carrier according to claim 1, wherein the modulized components are assembled into the second frame by using screws.

6. The circuit board carrier according to claim 1, wherein the second frame is assembled to the first frame by using screws and thermosetting plastic.

7. The circuit board carrier according to claim 1, wherein any one of the supporting portions comprises a supporting block and the supporting block is protruded from the second frame to contact the surface of the circuit board.

8. The circuit board carrier according to claim 1, wherein any one of the supporting portions comprises a supporting post and the supporting post is protruded from the second frame to contact the surface of the circuit board.

9. The circuit board carrier according to claim 1, wherein the second frame has a plurality of positioning portions and the positioning portions are protruded from the second frame to position the circuit board onto the second frame.

10. The circuit board carrier according to claim 9, wherein the positioning portions comprise a plurality of positioning pins and the positioning pins are protruded from the second frame to respectively pass through a plurality of through holes of the circuit board to position the circuit board onto the second frame.

11. A circuit board carrier, suitable for carrying a circuit board; the circuit board carrier comprising:
a first frame; and
a second frame, formed by connecting a plurality of modulized components and assembled with the first frame, wherein the second frame has a plurality of supporting portions to support a surface of the circuit board.

12. The circuit board carrier according to claim 11, wherein the first frame comprises an outer frame and a plurality of supporting beams, the supporting beams are connected to the outer frame and are assembled to the outer frame by using screws.

13. The circuit board carrier according to claim 11, wherein the first frame has a plurality of assembling holes and the second frame is assembled to the first frame by using a part of the assembling holes.

14. The circuit board carrier according to claim 11, wherein the modulized components are assembled into the second frame following the profile of a side frame of the circuit board.

15. The circuit board carrier according to claim 11, wherein the modulized components are assembled into the second frame by using screws.

16. The circuit board carrier according to claim 11, wherein the second frame is assembled to the first frame by using screws and thermosetting plastic.

17. The circuit board carrier according to claim 11, wherein any one of the supporting portions comprises a supporting block and the supporting block is protruded from the second frame to contact the surface of the circuit board.

18. The circuit board carrier according to claim 11, wherein any one of the supporting portions comprises a supporting post and the supporting post is protruded from the second frame to contact the surface of the circuit board.

19. The circuit board carrier according to claim 11, wherein the second frame has a plurality of positioning portions and the positioning portions are protruded from the second frame to position the circuit board onto the second frame.

20. The circuit board carrier according to claim 19, wherein the positioning portions comprise a plurality of positioning pins and the positioning pins are protruded from the second frame to respectively pass through a plurality of through holes of the circuit board to position the circuit board onto the second frame.
